(19) United States
(12) Patent Application Publication
(10) Pub. No.: US 2009/0195865 A1
(43) Pub. Date: Aug. 6, 2009

(54) INFRARED RADIATION REFLECTING LAYER SYSTEM AND METHOD FOR THE PRODUCTION THEREOF

(75) Inventors: Gerd Kleideiter, Ahaus (DE); Michael Geisler, Waechtersbach (DE); Udo Schreiber, Jossgrund (DE); Sven Schramm, Wuerzburg (DE)

Correspondence Address: PATTERSON & SHERIDAN, L.L.P., 3040 POST OAK BOULEVARD, SUITE 1500, HOUSTON, TX, 77056, US

(73) Assignee: APPLIED MATERIALS GMBH & CO. KG, ALZENAU (DE)

(21) Appl. No.: 12/280,151

(22) PCT Filed: Feb. 15, 2007
(86) PCT No.: PCT/EP2007/001334

§ 371 Date: Nov. 21, 2008

(30) Foreign Application Priority Data
Mar. 3, 2006 (EP) 06004325.4

(51) Int. Cl. G02B 5/26; G02B 1/10; C23C 14/10; C23C 14/14

(52) U.S. Cl. 359/360; 359/359; 204/192.27; 204/192.22

(57) ABSTRACT

The invention relates to an infrared radiation reflecting layer system for panes of glass and similar, the properties of said layer system being maintained even after heat treatment, for example, for bending or hardening the panes of glass. Silver is used as the infrared radiation reflecting layer. A combination of NiCrOₓ and Zn(Al)Oₓ is used as a lower-layer blocker for the silver. Also, a stoichiometric layer is also used as a pre-blocker layer. A specific work point is selected for a first dielectric layer of TiOₓN_{y}. Harmonisation of the thickness of the layers and the degrees of oxidation of NiCrOₓ and ZnAlOₓ as double lower-layer blockers and the work point of the TiOₓN_{y}-base layer are important for the temperability of the coating.

The invention relates to an infrared radiation-reflecting layer system according to the preamble of patent claim I as well as a method for its production according to patent claim 29.

Coated substrates play a major role when used in buildings or vehicles. Herein, it is in particular large-area glass panes which must be coated in order to be subsequently installed as architectural glass in buildings or as automobile glass in vehicles.

The requirements made of the glass are high. Although sufficient visible light must come through the glass, no UV light is frequently allowed to pass through it. The glass should also simultaneously serve for thermal regulation, which is attained thereby that onto the glass are applied electrically highly conducting layers, frequently a metal such as Cu, Ag, Au with a very low radiation emission coefficient. These layer systems including at least one layer as an infrared radiation reflecting layer of Cu, Ag or Au are also referred to as low-e (low emissivity or low emission) layers since they output only low thermal radiation of the room of a building to the outside.

Due to the light reflection of these low-e layers, which is often too high, these layers are provided with additional transparent coatings that act as antireflection layers. By applying these transparent layers, the desired color tint of the glass panes can also be set. The layers applied onto the infrared radiation reflecting layers serve, moreover, also for high chemical and mechanical resistance of the layer system.

Apart from the customary mechanical and chemical loading, the glass pane thus produced—if it is not to be curved and/or tempered—must also endure a temperature or bending process without suffering damage.

A pane of a translucent material with high transmission behavior in the visible range and very high reflection behavior in the heat radiation range as well as a method for its production is already known (DE 195 20 843 A1). Onto this pane is applied a coating comprised of several layers, Ag forming the infrared radiation reflecting layer proper. The pane provided with the coating is here not tempered or curved.

A coated substrate is furthermore known which is provided with at least one metallic coating layer and further dielectric layers (EP 1 089 947 B 1). The coated substrate is here only once heat treated. In order to protect the metal layer, in the coating process the metal layer is sandwiched between sublayers based on partially oxidized metals. This coated substrate is so structured that it can be tempered or curved. For this purpose and before each heat treatment every dielectric coating layer is provided with a sublayer based on a partially oxidized combination of two metals.

A multilayer system applied on a substrate, which system is also temperable and curvable, is also known (U.S. Pat. No. 6,576,349 B2, U.S. Pat. No. 6,686,050 B2). The multilayer system here comprises two infrared radiation reflecting layers, each of which is sandwiched between two NiCrOₓ layers.

Lastly is known a heat insulating layer system which is tempered and curved after the coating (DE 198 50 023 A1 or EP 0 999 192 B 1). This layer system includes an inert metal layer disposed on a TiO₂ layer, the two layers being sandwiched between suboxidic NiCrOₓ.

Building on DE 198 50 023 A1, the invention addresses the problem of producing a temperable and curvable coating on a substrate, which coating includes at least one infrared radiation reflecting layer, wherein it is prevented that during the tempering the metal layer, for example Ag, is attacked by oxygen or Na⁺ ions penetrating into it.

The problem addressed by the invention is solved according to the features of patent claims 1 or 29.

The invention thus relates to an infrared radiation reflecting layer system for glass panes and the like, the properties of the layer system being maintained even after a heat treatment, for example for curving or tempering the glass panes. As the layer reflecting infrared radiation proper, silver is utilized. As subblocker for this silver a combination of NiCrOₓ and ZnAlOₓ is employed. In addition, a stoichiometric layer is introduced as a preblocker. For a first dielectric layer of TiOₓN_{y} a special operating point is selected. Important for the temperability of the coating are the matching of layer thicknesses and the degree of oxidation of NiCrOₓ and ZnAlOₓ as a double subblocker as well as the operating point of the TiOₓN_{y} base layer.

With the invention a coating is provided which, in spite of tempering processes, remains color-neutral.

In order for oxygen not to be able to penetrate from the outside into the infrared radiation reflecting layer during the tempering, i.e. during the heating and subsequent cooling, two dielectric layers are disposed directly on the substrate.

The first dielectric layer not only serves as a blocker layer against oxygen but rather ensures, in addition, the stability of the optical parameters after the tempering. Utilized is preferably a TiO₂ or a TiOₓN_{y} layer, since in this case an especially good mechanical stability of the coated substrate is ensured.

Onto this first dielectric layer is applied a second dielectric layer. This second layer, preferably Si₃N₄, serves as a preblocker layer. Thereby that this preblocker layer has a precisely defined stoichiometry, it has especially good properties with respect to impermeability to oxygen.

Onto this layer is applied a blocker layer, preferably NiCrOₓ. The advantage of the use of a preblocker is further also that the oxygen content of the NiCrOₓ layer no longer needs to be precisely set.

Color neutrality before and after tempering, chemical and mechanical stability of the system as well as thermal loadability are attained through the combination of preblocker (for example Si₃N₄), blocker (for example NiCrOₓ) and adhesion promoter (for example ZnAlOₓ).

Due to the first layer, especially in the case of TiOₓN_{y}, for one, the color neutrality of the coated substrate is maintained, for another, application of a second dielectric layer as a preblocker prevents oxygen or other substances, such as for example Na⁺ ions, from penetrating into the succeeding layers. Therewith is ensured that the chemical and also the mechanical resistance of the coated substrate is maintained.

If the layer sequence of first dielectric and preblocker is interchanged, a blocker can be omitted.

Due to this layer sequence without a blocker, an especially high transmission is attained.

Embodiment examples of the invention are shown in the drawing and will be explained in further detail in the following. In the drawing depict:

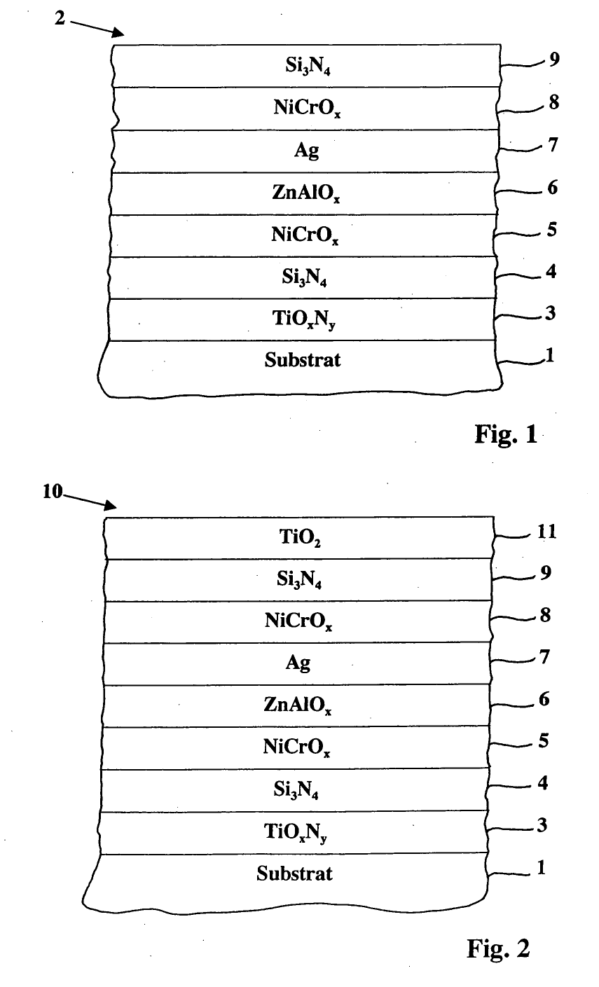

FIG. 1 a coating system disposed on a substrate, with an infrared radiation reflecting layer,

FIG. 2 a variant of the coating system shown in FIG. 1,

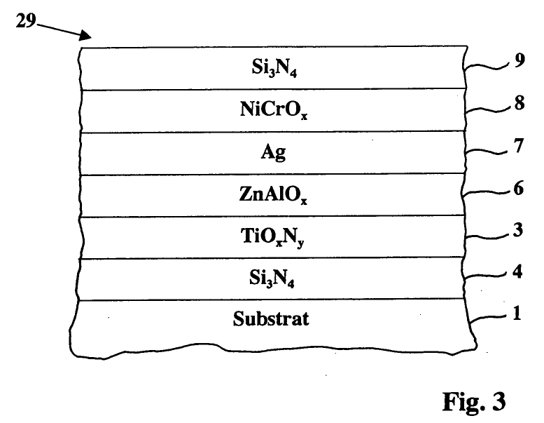

FIG. 3 a further variant of the coating system shown in FIG. 1,

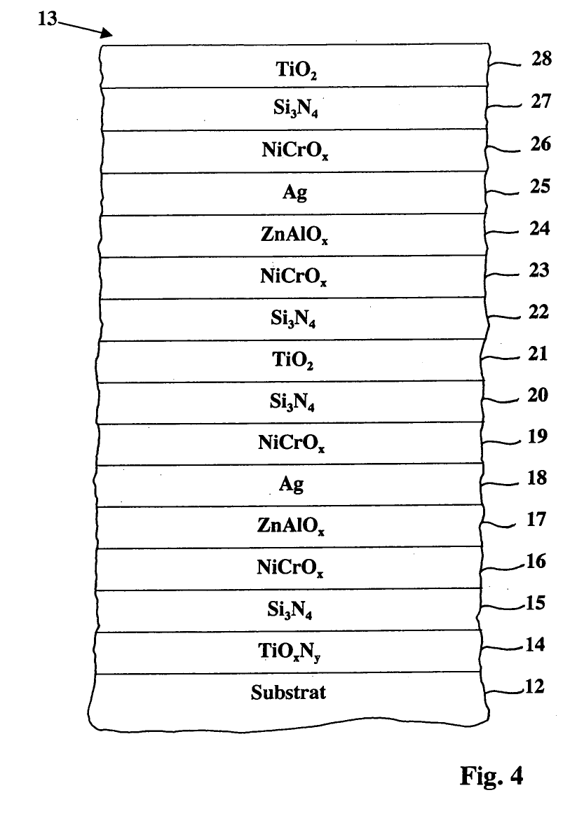

FIG. 4 a coating system disposed on a substrate, with two infrared radiation reflecting layers.

FIG. 1 depicts a coating system 2 disposed on a substrate 1. This coating system 2 comprises several layers 3 to 9 and is produced through a sputter process, each layer 3 to 9 being sputtered sequentially.

On the substrate 1, preferably glass, a first dielectric layer 3 is applied by means of reactive sputtering. This layer 3 comprises a dielectric, such as for example ZnO, SnO₂ In₂O₃, Bi₂O₃, TiO₂, ZrO₂, Ta₂O₅, SiO₂, Al₂O₃, AlN, Si₃N₄ or TiOₓN_{y}, however preferably TiO₂, Si₃N₄ or TiOₓN_{y}. Precisely the compound of type TiOₓN_{y} as well as TiO₂ has been found to be especially advantageous since the coated substrate 1 offers especially good color stability after the tempering, wherein the desired chemical and mechanical resistance is maintained or is even increased compared to a substrate that had been coated with a compound other than TiOₓN_{y} or TiO₂.

TiOₓN_{y} is obtained through reactive sputtering in transition mode of a metal target. In this case sputtering takes place preferably employing an MF technique, most often with a stabilizing regulation such as for example with an oxygen sensor or PEM (=Plasma Emission Measurement).

However, if TiO₂ is to form layer 3, TiO₂ can also be sputtered from a ceramic TiOₓ target. Although a small quantity of oxygen is added to the argon, the sputtering here does not involve reactive sputtering. Sputtering takes place by means of MF or DC technique, the DC technique being the more cost effective one. Hysteresis characteristics or transition modes do not occur in this process.

If TiOₓN_{y} is selected as the first layer 3 disposed on the substrate 1, on this layer 3 a further dielectric layer 4 must be disposed in order for oxygen or sodium ions not to penetrate into the upper layers.

With the exception of TiOₓN_{y}, this layer 4 superjacent on layer 3 can contain, one of the compounds that are also comprised in layer 3. However, preferably Si₃N₄ or TiO₂ are utilized. Consequently, layer 4 acts as a preblocker since it includes only stoichiometric compounds and is disposed before a blocker layer in order to prevent that oxygen penetrates into the upper layers or at least to decrease markedly the diffusion of oxygen. This makes the stoichiometry of the upper layers noncritical.

Layer 4 prevents that oxygen or sodium ions penetrate into the upper layers 5 to 9, whereby the chemical and mechanical resistance of the coated substrate is also maintained after the tempering.

However, if layer 3 is comprised of a stoichiometric compound, a second dielectric layer 4 applied thereon becomes superfluous, since layer 3 has already such a blocker property against oxygen or sodium ions. Nevertheless, such a layer 4 can optionally be applied onto layer 3.

The total thickness of layers 3 and 4 is approximately 25 nm, the thickness of layer 3 being approximately 15 to 19 nm and, consequently, is always greater than layer 4.

Onto layer 4 is applied a layer 5. This layer 5 serves as a blocker layer against oxygen, and this layer can be comprised of Ti, TiOₓ, Cr, CrOₓ, Nb, NbOₓ, NiCr or NiCrOₓ, however, preferably of NiCr or NiCrOₓ. Precisely in the case of the nonstoichiometric layer of the composition NiCrOₓ the blocker property against oxygen must be judged to be good since the oxygen can be incorporated into the NiCr metallic lattice due to the defects. This layer 5 has a layer thickness of approximately 3 to 6 nm.

Onto this layer 5 a further layer 6 is applied through reactive sputtering. This layer 6 comprises TaOₓ, ZnOₓ, ZnTaOₓ or ZnAlOₓ, with ZnAlOₓ being preferably utilized.

One capability for applying ZnAlOₓ comprises sputtering a metal target by means of MF technique. This metal target herein comprises Al as well as also Zn.

ZnAlOₓ is preferably obtained by sputtering a ceramic target. Since this ZnAlOₓ layer is a substoichiometric layer, sputtering can take place under Ar atmosphere, with small quantities of O₂ being added to the Ar. However, sputtering under an atmosphere of pure argon is also feasible.

Small quantities of O₂ are preferably added in case the ZnAlOₓ layer is to have low absorption, for example an absorption of 1 to 2%.

In contrast to the compounds of layer 5, TaOₓ, ZnOₓ, ZnTaOₓ or ZnAlOₓ not only have blocker properties against oxygen, but also good adhesion properties for the infrared radiation reflecting layers applied on them. These infrared radiation reflecting layers preferably comprise a metal of the first subgroup of the periodic system of elements or an alloy of at least one of these metals. If the infrared radiation reflecting layer were to be applied onto an NiCrOₓ layer, the oxygen content of this NiCrOₓ layer would need to be set precisely. If the oxygen content is too low, the NiCrOₓ layer is too metallic and the adhesive strength with respect to the applied metal layer 7 is too low. If, on the other hand, the oxygen content is too high, the NiCrOₓ layer does not have good blocker properties against the oxygen.

If the oxygen content is too high, the suboxidic layer NiCrOₓ is not capable of taking up sufficient oxygen during the tempering. The oxygen would therefore penetrate into the infrared radiation reflecting layer whereby the chemical resistance of this metal layer would be impaired. These problems are circumvented by applying a second blocker layer, layer 6. For layer 6

is preferably utilized ZnAlOₓ, which is applied by reactive sputtering. Compared to ZnOₓ, which is frequently utilized (for example DE 195 20 843 A1) and also has good adhesive strength, ZnAlOₓ has the advantage that the adhesive strength with respect to the infrared radiation reflecting layer is also maintained during the tempering.

Since very low layer thicknesses of layer 6 are already sufficient to obtain good growth of the infrared radiation reflecting layers, a layer thickness of approximately 1 nm is adequate.

Onto layer 6 is applied an infrared radiation reflecting layer 7. This infrared radiation reflecting layer comprises a metal of the first subgroup of the periodic system of elements or an alloy of at least one of these metals. However, the infrared radiation reflecting layer preferably comprises Ag, the Ag being applied by sputtering under oxygen. This oxygen incorporated into the Ag layer entails good chemical resistance. The layer thicknesses of these Ag layers are approximately 11 to 13 nm.

Onto the Ag layer 7, again, a blocker layer 8 is applied. This layer 8 preferably comprises NiCrOₓ, wherein Ti, TiOₓ, Cr, CrOₓ, Nb, NbOₓ or NiCr can also form the layer 8.

The thickness of layer 8 is approximately 3 to 6 nm. As the last layer follows a dielectric layer 9 that can comprise one of the elements of which also the second dielectric layer 4 is comprised. Layer 9, as is also shown in FIG. 1, is preferably comprised of Si₃N₄. The layer thickness of layer 9 is approximately 30 to 45 nm.

Compared to other layer systems, the layer system shown in FIG. 1 has the following advantages:

Due to layer 3, which comprises TiOₓN_{y}, it is ensured that the coated substrate can be curved during the tempering without the coated substrate undergoing impairment in mechanical and chemical resistance. The nitrogen in the TiO₂ reduces stress, which, in the case of relatively thick layers, is of advantage in so far as the tendency to cracking and pinholes in the coating is thereby reduced.

Layer 4 serving as a preblocker reduces the penetration of sodium ions as well as oxygen into the upper layers 5 to 9.

Onto layer 5 comprising NiCrOₓ an adhesion layer 6 is applied, which simultaneously serves also as a blocker layer. The oxygen content of the NiCrOₓ layer therefore no longer needs to be set precisely. This layer 6 preferably comprises ZnAlOₓ.

Layer 6 has good adhesive strength with respect to the infrared radiation reflecting layer 7.

Since Si₃N₄ and Ag adhere poorly to one another, at least one layer of another material must be applied in between as an adhesion promoter. Since ZnAlOₓ is possibly so thin that it does not form a closed layer, a further material must additionally be located between Si₃N₄ and Ag. This material is either TiO₂ or TiOₓN_{y} or NiCrOₓ. With the configuration ‘glass/Si₃N₄/TiO₂/Ag . . . TiOₓN_{y}’ the NiCrOₓ beneath the Ag can be omitted and, consequently, in the layout of a coating installation for double silver low-e two coating stations with the associated gas separations can be omitted which saves space and costs. Instead of TiO₂, TiOₓN_{y} can also be utilized at each site of the layer system.

Due to the good adhesive strength of layer 6, the Ag layer 7 disposed in FIG. 1 on ZnAlOₓ can be of a very low layer thickness compared to other layers on which an Ag layer is disposed.

In spite of this rather low layer thickness, the Ag layer has very good IR reflection since the surface resistivity is maintained. This is due not least to the fact that the Ag layer can grow optimally on a ZnAlOₓ layer.

FIG. 2 shows a variant of the coated substrate 1 depicted in FIG. 1. In contrast to the coating system 2 in FIG. 1, a further layer 11 is applied on the coating system 10. This layer 11 can consist of or comprise ZnO, SnO₂, In₂O₃, Bi₂O₃, TiO₂, ZrO₂, Ta₂O₅, SiO₂, Al₂O₃, AlN or Si₃N₄, however, preferably Si₃N₄ or TiO₂. As a cover layer, TiO₂ improves the chemical resistance of the layer system 10.

Since layer 9 comprises Si₃N₄, layer 11 is coated with TiO₂ by reactive sputtering. However, it is also conceivable that layer 11 is applied by sputtering a ceramic target. Thereby that onto layer 9 a further layer 11 had been applied, the layer thickness of layer 9 can be reduced. The sum of the two layer thicknesses of layers 9 and 11 can preferably also continue to have a total thickness of approximately 37 to 44 nm. Of advantage is here that by applying two dielectric layers 9 and 11 of different composition, the properties of the compounds complement each other.

In the following the process of applying the discrete layers will be described. Layers 3 to 9 and 11 of layer system 10 or layers 3 to 9 of layer system 2 in FIG. 1 are preferably applied by reactive sputtering and/or by sputtering a ceramic target. Although layers 5, 6, 7, 8 can also be applied by sputtering the corresponding metallic target under argon,

sputtering under argon with small quantities of oxygen is of advantage, for example in the case of Ti, Nb, Cr, Ag, NiCr, since the layers 5, 6, 8, if they are comprised of suboxidic compounds, have better blocker properties against oxygen and, in the case of Ag, the chemical resistance is improved through the incorporation of oxygen, compared to a layer of pure Ag.

Although silver is sometimes sputtered using an addition of oxygen, this procedure cannot be considered to be reactive sputtering. When sputtering using an addition of oxygen, the plasma discharge is not determined by the oxygen. The target surface is substantially metallic, and the discharge therewith behaves like a metallic sputter process. Rather, the layer that has been sputtered on can be referred to as oxygen-doped, i.e. it is substantially comprised of silver that contains a few percent of silver oxide. The process gas contains markedly less than 10%, the oxygen fractions are rather I to 5%. To sputter silver reactively, an oxygen fraction of at least 50% would be required in the process gas. Layers of reactively deposited silver oxide would, in fact, be dark to black.

The sputter process for all layers is carried out at a pressure of approximately 2×10⁻³ to 5×10⁻³ mbar. To the inert gas, preferably Ar, is added reactive gas, preferably O₂ or N₂. The ratio of Ar: O₂ is preferably 3:1, and, if N₂ is also required for the production of the layer, as in the case of a TiOₓN_{y} layer, the ratio of O₂:N₂ is 5:1.

This pressure as well as the relative ratio of the gases have been found to be optimal for the sputter process for the production of these layers, although it is also feasible to work with another pressure and another composition of the gas mixture.

Apart from these two parameters, the power at which sputtering takes place also plays a large role.

FIG. 3 depicts a further variant of the coating system 2 shown in FIG. 1. In the coating system 29 shown in FIG. 3 not the layer 3, but rather the layer 4 is disposed directly on substrate 1. Layer 3 and 4, consequently, have changed places.

Although layer 3 in FIG. 3 comprises TiOₓN_{y}, layer 3 can also comprise TiO₂. Thereby that layer 3 is now no longer disposed on the substrate 1, the chemical and mechanical resistance decreases. However, through this disposition on layer 5, the NiCrOₓ blocker layer can be omitted since the ZnAlOₓ layer adheres better on the TiOₓN_{y} layer than on the Si₃N₄ layer.

In this coating system 29 it is advantageous that by omitting the first blocker layer, the transmission is increased compared to the coating system 2 depicted in FIG. 1 or 2.

Thus, this coating system is of advantage if increased transmission is desired and lower requirements are to be made of the mechanical and chemical resistance.

Although not shown in FIG. 3, onto layer 9 a further layer 11, analogous to FIG. 2, can be applied, the layer 11 preferably comprising TiO₂.

FIG. 4 shows a coating system 13 disposed on a substrate 12 with two infrared radiation reflecting layers 18, 25.

As can be seen in FIG. 4, layers 14 to 21 do not differ in their composition and sequence from the coating system 10 depicted in FIG. 2. Onto layer 21 are applied seven further layers, namely layers 22 to 28. Layer 25 is the additionally applied infrared radiation reflecting layer.

Layers 22 to 28 sputtered onto layer 21 have the same composition and also sequence as the seven layers 15 to 21. Consequently, after the substrate 12 has been coated with a first dielectric layer 14, it is twice in succession coated with the layer sequence Si₃N₄, NiCrOₓ, ZnAlOₓ, Ag, NiCrOₓ, Si₃N₄ and TiO₂. Therewith a coating system with only one infrared radiation reflecting layer becomes the coating system 13 with two infrared radiation reflecting layers.

As is evident, apart from the TiOₓN_{y} layer, the coating system 13 comprises in principle two coating systems 10 stacked one on top of the other. This has the advantage that in a sputter process the same target material can be used. If, onto the substrate 12, layers 14 to 21 have been applied, the coating process can simply be repeated without the target material having to be replaced by an entirely new and different target material.

Since FIG. 4 depicts a preferred coating system 13 with two infrared radiation reflecting layers 18, 25, the composition can also vary.

Although layer 14 is preferably consists of TiOₓN_{y}, layer 14 can comprise ZnO, SnO₂, In₂O₃, Bi₂O₃, TiO₂, ZrO₂, Ta₂O₅, SiO₂, Al₂O₃, AlN or Si₃N₄.

In contrast, layers 15, 20, 21, 22, 27, 28 can comprise at least one compound from the series Si₃N₄, AlN, Al₂O₃, SiO₂, Ta₂O₅, ZrO₂, TiO₂, Bi₂O₃, In₂O₃, SnO₂ and/or ZnO. These layers are applied by reactive sputtering or by sputtering of a corresponding ceramic target.

Layers 16, 19, 23, 26 can comprise Ti, TiOₓ, Cr, CrOₓ, Nb, NbOₓ, NiCr or NiCrOₓ. The adhesion layers 17, 24 comprise TaO, ZnOₓ, ZnTaOₓ or ZnAlOₓ.

While the infrared radiation reflecting layers 18, 25 preferably comprise Ag, they can, however, also comprise Cu, Au or an alloy of these metals.

The layer thicknesses of the coating system 13 differ minimally from a coating system with only one infrared radiation reflecting layer as shown in FIG. 1 to 3.

Only in the thickness of layers 20 to 22 is there a difference. Although the thickness of layers 20 to 22 can be different, the sum of the layer thicknesses of these layers 20 to 22 is approximately 70 to 90 nm.

The materials of layers 20 to 22 are interchangeable such that layer 21 can comprise Si₃N₄ and layers 20, 22 can comprise TiO₂.

It is also feasible that between the NiCrOₓ layers 19, 23 only two or even only one layer is disposed. If, for example, two layers are disposed between the two NiCrOₓ layers 19, 23, the one layer can be comprised, for example, of TiO₂ and the other layer of Si₃N₄. The sequence of the layers is not critical.

In this coating system 13 the layer 15 can also be interchanged with layer 14. Since now layer 15 is disposed on the substrate 12, the chemical and mechanical resistance does indeed decrease, however, thereby layers 16 and 23 can be omitted whereby the transmission of the coating system 13 can be increased.

A coating system with more than two infrared radiation reflecting layers is also conceivable. It should here be taken into consideration that a coating system with only one infrared radiation reflecting layer compared to a coating system with two infrared radiation reflecting layers has a transmission of visible light which is lower by approximately 5 to 10%. Thus, the transmission decreases with increasing number of infrared radiation reflecting layers. However, a coating system with two infrared radiation reflecting layers has the advantage that the IR reflection is increased by nearly 100%. A coating system with two infrared radiation reflecting layers thus offers very good thermal regulation at only a minimal loss of transmission.

The selectivity S of these systems is significantly higher, the selectivity S being calculated as

$$S = \frac{{T}_{vis}}{{T}_{IR}} ,$$

with Tᵥᵢₛ=transmission in the visible range and T_{IR}=transmission in the infrared range.

1. Infrared radiation reflecting layer system, in particular for glass sheets to be curved and/or to be tempered, with at least one infrared radiation reflecting layer, comprising:
a) a first dielectric layer (3, 14) disposed on a substrate (1, 12), followed by
b) a first blocker layer (5, 16),
c) an adhesion mediating layer (6, 17, 24),
d) an infrared radiation reflecting layer (7, 18, 25),
e) a second blocker layer (8, 19, 26) as well as
f) a second dielectric layer (9, 20, 27),
characterized in that between the first dielectric layer (3, 14) and the first blocker layer (5, 16) a preblocker layer (4, 15) is disposed.

2. Layer system as claimed in claim 1, characterized in that the first dielectric layer (3, 14) consists of ZnO, SnO₂, In₂O₃, Bi₂O₃, TiO₂, ZrO₂, Ta₂O₅, Al₂O₃, AlN, Si₃N₄ and/or TiOₓN_{y} or comprises these substances.

3. Layer system as claimed in claim 2, characterized in that the first dielectric layer (3, 14) is TiOₓN_{y}.

4. Layer system as claimed in claim 2, characterized in that the first dielectric layer (3, 14) is TiO₂.

5. Layer system as claimed in claim 1, characterized in that the first and the second blocker layer (5, 8, 16, 19, 23, 26) consist of TiOₓ, Ti, Ni, Cr, NiCr, Nb, NbOₓ, CrOₓ and/or NiCrOₓ or comprise these substances.

6. Layer system as claimed in claim 1, characterized in that the adhesion mediating layer (6, 17, 24) consists of ZnOₓ, TaOₓ, ZnTaOₓ and/or ZnAlOₓ or comprises these substances.

7. Layer system as claimed in claim 1, characterized in that the infrared radiation reflecting layer (7, 18, 25) consists of a metal of the first subgroup of the periodic system of elements and/or of an alloy of at least one of these metals or comprises these substances.

8. Layer system as claimed in claim 6, characterized in that the infrared radiation reflecting layer (7, 18, 25) consists of Ag or comprises Ag.

9. Layer system as claimed in claim 7 and claim 8, characterized in that the infrared radiation reflecting layer (7, 18, 25) comprises oxygen.

10. Layer system as claimed in claim 1, characterized in that the second dielectric layer (9, 20, 27) consists of Si₃N₄, TiO₂, AlN, Al₂O₃, SiO₂, Ta₂O₅, ZrO₂, Bi₂O₃, In₂O₃, SnO₂ and/or ZnO or comprises these substances.

11. Layer system as claimed in claim 1, characterized in that the preblocker layer (4, 15) is stoichiometrically structured.

12. Layer system as claimed in claim 11, characterized in that the preblocker layer (4, 15) consists of TiO₂ and/or Si₃N₄ or comprises these substances.

13. Layer system as claimed in claim 1, characterized in that on the second dielectric layer (9, 20, 27) a further layer (11, 21, 28) is disposed.

14. Layer system as claimed in claim 13, characterized in that the further layer (11, 21, 28) consists of TiO₂ or comprises TiO₂.

15. Infrared radiation reflecting layer system, in particular for glass sheets to be curved and/or to be tempered, with at least one infrared radiation reflecting layer, comprising:
a) a first preblocker (4, 15) disposed on a substrate (1, 12), followed by
b) a first dielectric layer (3, 14),
c) an adhesion mediating layer (6, 17, 24),
d) an infrared radiation reflecting layer (7, 18, 25),
e) a blocker layer (8, 19, 26) as well as
f) a second dielectric layer (9, 20, 27).

16. Layer system as claimed in claim 15, characterized in that on the second dielectric layer (9, 20, 27) a further layer (11, 21, 28) is disposed.

17. Layer system as claimed in claim 16, characterized in that the further layer (11, 21, 28) consists of TiO₂ or comprises TiO₂.

18. Layer system as claimed in claim 15, characterized in that the first dielectric layer (3, 14) consists of ZnO, SnO₂, In₂O₃, Bi₂O₃, TiO₂, ZrO₂, Ta₂O₅, Al₂O₃, AlN, Si₃N₄ and/or TiOₓN_{y} or comprises these substances.

19. Layer system as claimed in claim 18, characterized in that the first dielectric layer (3, 14) is TiOₓN_{y} or comprises TiOₓN_{y}.

20. Layer system as claimed in claim 18, characterized in that the first dielectric layer (3, 14) is TiO₂ or comprises TiO₂.

21. Layer system as claimed in claim 15, characterized in that the blocker layer (8, 19, 26) consists of TiOₓ, Ti, Ni, Cr, NiCr, Nb, NbOₓ, CrOₓ and/or NiCrOₓ or comprises these substances.

22. Layer system as claimed in claim 15, characterized in that the adhesion mediating layer (6, 17, 24) consists of ZrOₓ, TaOₓ, ZnTaOₓ and/or ZnAlOₓ or comprises these substances.

23. Layer system as claimed in claim 15, characterized in that the infrared radiation reflecting layer (7, 18, 25) consists of a metal of the first subgroup of the periodic system of elements and/or of an alloy or at least comprises one of these metals.

24. Layer system as claimed in claim 23, characterized in that the infrared radiation reflecting layer (7, 18, 25) consists of Ag or comprises Ag.

25. Layer system as claimed in claim 24, characterized in that the infrared radiation reflecting layer (7, 18, 25) comprises oxygen.

26. Layer system as claimed in claim 15, characterized in that the second dielectric layer (9, 20, 27) consists of Si₃N₄, TiO₂, AlN, Al₂O₃, SiO₂, Ta₂O₅, ZrO₂, Bi₂O₃, In₂O₃, SnO₂ and/or ZnO or comprises these substances.

27. Layer system as claimed in claim 15, characterized in that the preblocker layer (4, 15) is stoichiometrically structured.

28. Layer system as claimed in claim 27, characterized in that the preblocker layer (4, 15) consists of TiO₂ and/or Si₃N₄ or comprises these substances.

29. Method for the production of an infrared radiation reflecting layer system for curved and/or tempered glass sheets comprising the following steps:
a) a substrate (1, 12) is provided,
b) onto the substrate (1, 12) a first dielectric layer (3, 14) is applied,
c) onto this first dielectric layer (3, 14) a preblocker (4, 15) is applied,
d) onto the preblocker (4, 15) a first blocker layer (5, 16, 23) is applied,
e) onto this blocker layer (5, 16, 23) an adhesion mediating layer (6, 17, 24) is applied,
f) onto the adhesion mediating layer (6, 17, 24) an infrared radiation reflecting layer (7, 18, 25) is applied,
g) onto the infrared radiation reflecting layer (7, 18, 25) a second blocker layer (5, 19, 26) is applied,
h) onto this second blocker layer (5, 19, 26) a second dielectric layer (9, 20, 27) is applied.

30. Method as claimed in claim 29, characterized in that the first dielectric layer (3, 14) TiO₂ and/or TiOₓN_{y} is applied by sputtering a ceramic target.

31. Method as claimed in claim 29, characterized in that the first dielectric layer (3, 14) TiO₂ and/or TiOₓN_{y} is applied through reactive sputtering.

32. Method as claimed in claim 29, characterized in that the first and the second blocker layer (5, 8, 16, 19, 25, 26) Ti, TiO₂ Ni, Cr, NiCr, Nb, CrOₓ, NbOₓ, and/or NiCrOₓ are applied through reactive sputtering.

33. Method as claimed in claim 29, characterized in that the first and the second blocker layer (5, 8, 16, 19, 25, 26) Ti, TiOₓ, Ni, Cr, NiCr, Nb, CrOₓ, NbOₓ, and/or NiCrOₓ are applied through sputtering of a ceramic or of a metallic target under argon.

34. Method as claimed in claim 29, characterized in that the adhesion mediating layer (6, 17, 24) ZnAlOₓ is applied through reactive sputtering of a metal target.

35. Method as claimed in claim 29, characterized in that the adhesion mediating layer (6, 17, 24) ZnAlOₓ is applied through sputtering of a ceramic target.

36. Method as claimed in claim 29, characterized in that the infrared radiation reflecting layer is applied through sputtering while adding minimal quantities of oxygen.

37. Method as claimed in claim 29, characterized in that the second dielectric layer (9, 21) TiO₂, Si₃N₄, AlN, Al₂O₃, SiO₂, Ta₂O₅, ZrO₂, Bi₂O₃, In₂O₃, SnO₂ and/or ZnO is applied by means of reactive sputtering.

38. Method as claimed in claim 29, characterized in that the second dielectric layer (9, 21) TiO₂, Si₃N₄, AlN, Al₂O₃, SiO₂, Ta₂O₅, ZrO₂, Bi₂O₃, In₂O₃, SnO₂ and/or ZnO is applied by sputtering of a ceramic target.

39. Method as claimed in claim 29, characterized in that onto the second dielectric layer (9, 20, 27) further dielectric layers (21, 22) are applied through reactive sputtering.

40. Method as claimed in claim 29, characterized in that onto the second dielectric layer (9, 20, 27) further dielectric layers (21, 22) are applied through sputtering of a ceramic target.

41. Method as claimed in claim 29, characterized in that steps d) to h) are repeated.
